(19) United States
(12) Patent Application Publication
(10) Pub. No.: US 2023/0400778 A1
(43) Pub. Date: Dec. 14, 2023

(54) METHODS AND COMPUTER PROGRAMS FOR CONFIGURATION OF A SAMPLING SCHEME GENERATION MODEL

(71) Applicant: ASML NETHERLANDS B.V., Veldhoven (NL)

(72) Inventors: Roy WERKMAN, Eindhoven (NL); Jochem Sebastiaan WILDENBERG, Aarle-Rixtel (NL); Reza SAHRAEIAN, Eindhoven (NL)

(73) Assignee: ASML NETHERLANDS B.V., Veldhoven (NL)

(21) Appl. No.: 18/032,273

(22) PCT Filed: Oct. 26, 2021
(86) PCT No.: PCT/EP2021/079621

§ 371 Date: Apr. 17, 2023

(30) Foreign Application Priority Data
Nov. 11, 2020 (EP) 20206977.9

(51) Int. Cl. G03F 7/00; G06N 3/045; G06N 3/0475; G06N 3/094

(52) U.S. Cl. CPC G03F 7/705; G06N 3/045; G06N 3/0475; G06N 3/094

(57) ABSTRACT

A method to infer a current sampling scheme for one or more current substrates is provided, the method including: obtaining a first model trained to infer an optimal sampling scheme based on inputting context and/or pre-exposure data associated with one or more previous substrates, wherein the first model is trained in dependency of an outcome of a second model configured to discriminate between the inferred optimal sampling scheme and a pre-determined optimal sampling scheme; and using the obtained first model to infer the current sampling scheme based on inputting context and/or pre-exposure data associated with the one or more current substrate.

### CROSS-REFERENCE TO RELATED APPLICATIONS

This application claims priority of EP application 20206977.9 which was filed on Nov. 11, 2020 and which is incorporated herein in its entirety by reference.

### FIELD

The present invention relates to methods and computer programs arranged for configuring a model for sampling scheme generation. Specifically, the sampling scheme relates to a distribution of sampling locations across a substrate subject to a lithographic process and selection of substrates within a lot for measurement.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k1 lithography may be used to process features with dimensions smaller than the classical resolution limit of a lithographic apparatus. In such process, the resolution formula may be expressed as CD=k1×λ/NA, where λ is the wavelength of radiation employed, NA is the numerical aperture of the projection optics in the lithographic apparatus, CD is the “critical dimension” (generally the smallest feature size printed, but in this case half-pitch) and k1 is an empirical resolution factor. In general, the smaller k1 the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

Lithographic processes often need sufficient data in order to enable monitoring and/or control of an apparatus being used in the lithographic process, such as a lithographic tool, etcher tool or a deposition tool. The data may be metrology data comprising measurements performed on substrates patterned by the lithographic apparatus. The measurements are typically performed on pre-determined locations across the substrate(s), the so-called “sampling locations”. Typically a sampling scheme generation algorithm is used to determine these (optimal) sampling locations, for example based on knowledge of a model used to describe the measurement data and/or based on a typically observed distribution of the measurement data (values) across one or more substrates.

Measurement on each sampling location takes valuable metrology time which could have been used for lithographic processing of substrates contributing directly to the creation of semiconductor devices manufactured by said lithographic process. In addition when it is required that many sampling locations are measured often multiple metrology tools are needed, costing valuable floor space. Hence it is of paramount interest that the utilized sampling scheme generator is cost effective as well; preventing that more sampling locations will be defined than necessary for acceptable process monitoring/control purposes. A potential improvement of (static) sampling scheme generators has been proposed in the past. For example the sampling scheme generator as described in international patent application WO2017194289 is configured to more dynamically select sampling locations by recognizing a pattern across a first set of sampling locations and based on the recognized pattern select a second set of sampling locations (dynamically). However the above described dynamic sampling scheme generator is still relatively limited in truly customizing a (dynamic) sampling scheme (e.g. set of sampling locations) for a wide variety of potentially different patterns of measurement data across the one or more substrates; the sets of first and second sampling locations are typically pre-determined. The limitation of a pre-determined, but dynamically selectable, discrete set of sampling schemes may prevent optimal sampling of substrates as still more than required sampling locations may be subject to measurement while not strictly needed in view of satisfactory process monitoring and/or control.

It is an objective of the invention to provide a dynamic sampling scheme generating method configured to avoid definition of sampling locations which do add nothing or little to the quality of the process monitoring and/or process control.

### SUMMARY

It is an object of the present invention to provide methods and apparatus for configuring a sampling scheme generator.

According to a first aspect of the invention, there is provided a method comprising: obtaining a trained model configured to infer a preferred sampling scheme for a substrate based on measurement data comprising sampling locations on the substrate and corresponding measurement values; and using current measurement data associated with a current substrate as input for the trained model to determine whether further measurement on the current substrate is required.

According to a second aspect of the invention, there is provided a method to infer a current sampling scheme for one or more current substrates, the method comprising: obtaining a first model trained to infer an optimal sampling scheme based on inputting context and/or pre-exposure data associated with one or more previous substrates, wherein the first model is trained in dependency of an outcome of a second model configured to discriminate between the inferred optimal sampling scheme and a pre-determined optimal sampling scheme; and using the obtained first model to infer the current sampling scheme based on inputting context and/or pre-exposure data associated with the one or more current substrate.

According to a third aspect of the invention, there is provided a method for providing a decision on stopping or continuing performing measurements on sampling locations for one more substrates, the method comprising: obtaining an initial set of measurement values corresponding to an initial sampling scheme; obtaining a model comprising: i) a first model trained to infer from a set of measurement values whether one or more requirements imposed by a process monitoring and/or process control strategy are met; and ii) a second model trained to infer from a set of measurement values that one or more further measurement values need to be acquired before meeting said requirements imposed by the process monitoring and/or process control strategy; inputting the initial set of measurement values to the model to obtain the decision, wherein the decision is based on balancing the output of the first and the second model.

According to a fourth aspect of the invention there is provided a computer program product comprising computer readable instructions configured to implement the method of any preceding aspect of the invention.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 depicts a diagram representing a method according to an embodiment of the invention;

FIG. 5 depicts a diagram representing a method according to an embodiment of the invention;

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

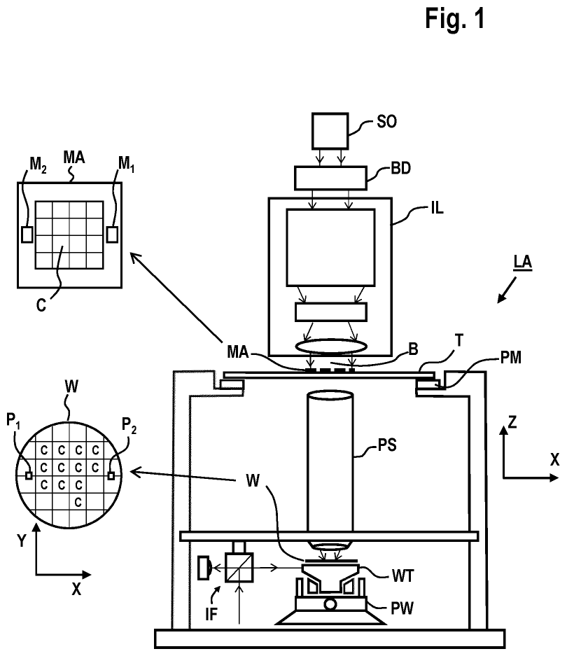

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

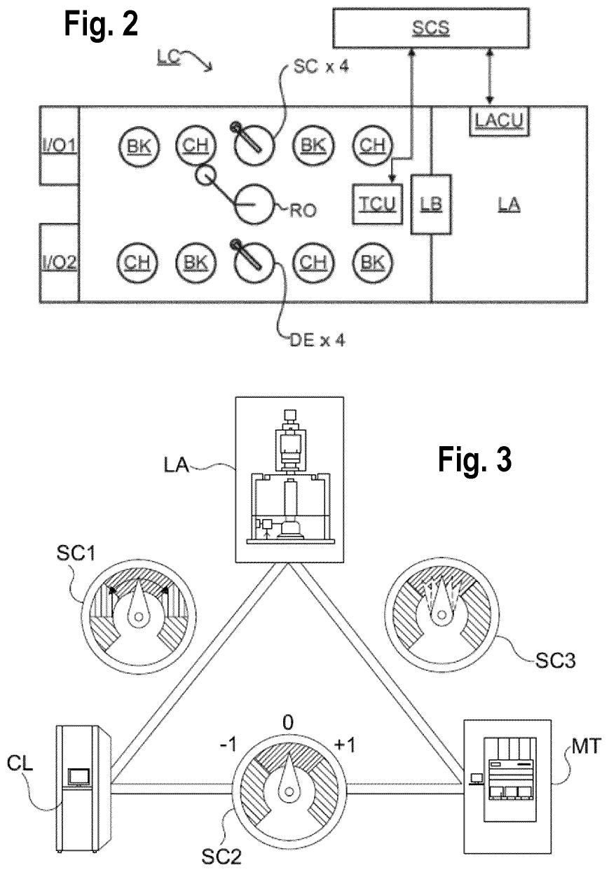

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

Metrology tools MT may measure a substrate during different stages of the lithographic patterning process. Metrology of a substrate may be used for different purposes. Measurements of a substrate may for example be used for monitoring and/or updating lithographic process settings, error detection, analysis of the apparatus over time, quality control etc. Some measurements are easier to obtain than others. For example, some measurements may require specific target structures present on a substrate. Some measurements may take a relatively long time to perform compared to other measurements. Long measurements may take up a lot of time in expensive metrology tools MT. This may make those measurements expensive in terms of equipment use and time. As a result, such measurements may be performed less frequently. This may mean that only sparse measurement data is available for some parameters, and/or that the measurements may not be performed on every substrate.

The cost of metrology time is to a large part determined by: a) the number of measurements taken per substrate; e.g. the number of sampling locations comprised within a utilized sampling scheme and b) the number of substrates measured per lot or thread. It is of paramount importance to select sampling locations in view of their informativeness. For example it may be assumed that the measurement data can be described accurately using a (polynomial) model mapping substrate coordinates to a modelled value of a measurement parameter. Knowledge of the model (base functions, behaviour) may be used to determine preferred sampling locations across the substrate, or a region on the substrate (a field or a die or a set of fields and/or dies). Alternatively historic measurement data may be used to determine the sampling scheme; for example based on one or more of: a) a typically observed fingerprint of the measurement parameter, wherein for example the density of the sampling locations scales with the spatial rate of change of the measurement parameter across the substrate (region) and b) previously determined measurement quality KPI distributions, for example leave out locations on the substrate prone to processing induced measurement errors.

So far no mechanism has been proposed to actively and dynamically analyse the measurements data obtained while the measurements are still in progress and dynamically evaluate the availability of measurement data and its sufficiency for process monitor and/or process control purposes. In case such a mechanism is in place it could provide sampling locations in real time; e.g. continuously propose sampling locations for measurement until a certain control/monitoring related requirement is met. The sampling locations in this proposed way of working are not static (pre-determined), but are generated in response to an expected (inferred) optimal sampling scheme.

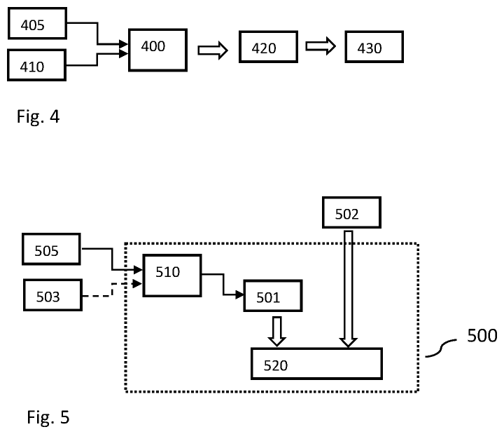

This approach may be implemented by using a model configured to predict a preferred sampling scheme based on various inputs. Typically such a model needs to be trained and is for example based on a neural network. The various inputs while using the model for dynamic sampling scheme determination comprise at least measurement data obtained for a substrate up till a certain time ‘t’ and preferably context and/or pre-exposure data such as alignment and levelling data associated with said substrate. Alternatively or additionally the pre-exposure data may comprise measurement data of one or more previous substrates or previous lots, for example measured overlay data of a previous lot which likely has an across substrate overlay fingerprint similar to the substrate. The context data may for example comprise the processing history of the substrate (e.g. identification of tools used in processing the substrate, for example the specific etch chamber, deposition tool or lithographic apparatus used in patterning the substrate). The model typically needs to be trained with historic measurement data associated with one or more previous sampling schemes, such as distributed sampling schemes wherein substrates within a lot are measured according to different sub-sampling schemes. In another example the measurement data comprises a mix of sparsely measured data and/or (less frequently measured) dense measurement data. Additionally to the measurement data also context data, pre-exposure data and sampling scheme data may be used as input for the training phase of the model. The training data may for example be historically determined optimal sampling schemes for already processed substrates including their associated context and/or pre-exposure data. The training phase establishes a first version of the model used in inferring optimized sampling schemes based on available measurement data and (if available) context and/or pre-exposure data. The available measurement data may extend beyond the measurement data of a certain substrate subject to inspection, it may include for example also measurement data for recently measured substrates (for example substrates belonging to the same lot as the substrate subject to inspection). Once trained the model may be used for dynamic sampling scheme definition; meaning that during substrate inspection data is continuously fed to the model and the inferred preferred sampling scheme is continuously benchmarked to the set of sampling locations which have been subject to measurement (inspection) so far. In case the already available sampling locations are in line (close enough) to the dynamically inferred optimal sampling scheme the model may communicate that further sampling of the substrate of interest may be stopped. Alternatively if there are still too few sampling locations inspected/measured the model may propose one or more sampling locations to be included for inspection/measurement. The model additionally may further specify which substrates out of one or more lots of substrates to measure and further specify for which substrates which sampling locations to select. This strategy is depicted in FIG. 4. Context and/or pre-exposure data 405 and current measurement data 410 are used as an input to a model 400 configured to infer an optimal sampling scheme and advice for further measurement action (e.g. selection of which substrates to measure and for each selected substrate the corresponding sampling locations), including proposing one or more further sampling locations and/or advising to continue by measuring the next sampling location or stopping measurement for the current substrate (e.g. the substrate being currently subject to measurement/inspection).

Further the current measurement data is used to update the model; by continuously offering measurement data corresponding to the determined optimal sampling scheme to the model the model is continuously trained and consequently the model incrementally becomes better trained and dynamically trained.

In an embodiment of the invention a method is provided, the method comprising: obtaining a trained model configured to infer a preferred sampling scheme for a substrate based on measurement data associated with the substrate; and using current measurement data associated with a current substrate as input for the trained model to determine whether further measurement on the current substrate is required.

In an embodiment the model is based on a neural network.

In an embodiment the measurement data comprises information of sampling locations associated with measurement values comprised within said measurement data.

In an embodiment the method further comprises inputting pre-exposure data and/or context data associated with the current substrate to the trained model.

In an embodiment the method further comprises configuring the trained model based on the current measurement data.

The trained model as described above may also be configured as a generative adversarial network (GAN). In this case the model comprises a generative model trained to generate a sampling scheme (based on adequate input data) and a discriminative model trained to distinguish between an inferred (optimal) sampling scheme (using the generative model) and an actual optimal sampling scheme.

FIG. 5 depicts a GAN based sampling scheme generator 510. The sampling generator 510 is part of a GAN 500 comprising also a discriminative model 520 trained to discriminate between a generated optimal sampling scheme 501 and a real optimized sampling scheme 502. The generator 510 is trained during a training phase by inputting one or more “worst case” sampling schemes 503, which are typically (very) dense sampling schemes configured to provide sufficient information for process monitoring and/or control for any condition (e.g. context/pre-exposure data content). Relevant context and/or pre-exposure data is provided to the generator 510 (and typically also to the discriminator 520) as input for generation of the optimized sampling scheme 501 which is typically sparser than the worst case sampling scheme 503. The generator 510 and discriminator 520 are trained together (in dependence of each other) such that the generator 510 is trained to provide a sampling scheme 501 which is better (sparser) than the worst case sampling scheme 503 while adequate for a given context and/or pre-exposure data condition. Adequate means here that the generated sampling scheme 501 is not distinguishable from a truly optimized sampling scheme 502 (first training goal). At the same time the discriminator is trained to increasingly become better in rejecting the generated optimal sampling scheme 501 as being a truly optimized sampling scheme 502 (second training goal). Both the generator and discriminator are typically neural networks.

Once the generator 510 is trained for different conditions (e.g. different sets of corresponding context and/or pre-exposure data) it may be used to derive a complete optimal sampling scheme for a substrate (or lot of substrates) based on the context and/or pre-exposure data corresponding to said substrate or lot of substrates.

In an embodiment a method to infer a current sampling scheme for one or more current substrates is provided, the method comprising: obtaining a first model trained to infer an optimal sampling scheme based on inputting context and/or pre-exposure data associated with one or more previous substrates, wherein the first model is trained in dependency of an outcome of a second model configured to discriminate between the inferred optimal sampling scheme and a pre-determined optimal sampling scheme; and using the obtained first model to infer the current sampling scheme based on inputting context and/or pre-exposure data associated with the one or more current substrate.

In an embodiment the first model is a generative model and the second model a discriminative model and the first and second model constitute a Generative Adversarial Network (GAN).

In an embodiment the first model is trained using input data comprising said context and/or pre-exposure data and a dense sampling scheme being more dense than said inferred current sampling scheme.

In an embodiment the dense sampling scheme is configured to be a sampling scheme expected to suffice for any condition of the substrate, wherein the condition is characterized by context and/or pre-exposure data associated with the substrate.

The GAN based sampling scheme generation as described above is based on prediction of a complete sampling scheme and guidance of what substrates to measure with what sampling scheme in one go. Alternatively also a more ad hoc sampling decision method may be devised based on a GAN like sampling scheme generation method. In this case acquired measurement data (for example obtained during point by point sampling of locations comprised within an initial sampling scheme) is continuously fed to a generative model which is trained to use the so far acquired measurement data (and if applicable also available context and/or pre-exposure data) to establish that the requirements on process monitoring/control are met and no further measurement is requested (e.g. skip measurement location(s), skip next substrate(s) for measurement). The opposite goal is pursued by the discriminative model having been trained to use the so far acquired data (and any potentially available context and/or pre-exposure data) to infer improvement potential of process monitoring/control is still considerable and the currently available measurement data is not sufficient, e.g. the discriminator is trained to find evidence in favour of continuing measurements. The objectives of the generative model and the discriminative model are hence opposite, the combined generative and discriminative model being configured to provide a balanced sampling decision. The combined model being usable to control measurements on sampling locations such that both sufficient measurement data will be acquired, while it is prevented that more measurement time is spend than strictly necessary to meet certain process monitoring and/or process control requirements.

In an embodiment a method for providing a decision on stopping or continuing performing measurements on sampling locations for one more substrates is provided, the method comprising: obtaining an initial set of measurement values corresponding to an initial sampling scheme; obtaining a model comprising i) a first model trained to infer from a set of measurement values that one or more requirements imposed by a process monitoring and/or process control strategy are met and ii) a second model trained to infer from a set of measurement values that one or more further measurement values need to be acquired before meeting said requirements imposed by the process monitoring and/or process control strategy; inputting the initial set of measurement values to the model to obtain the decision, wherein the decision is based on balancing the output of the first and the second model.

In an embodiment the first model is a generative model and the second model a discriminative model and the model is a Generative Adversarial Network (GAN).

The methods described herein may be executed using one or more processors performing instructions saved in memory accessible by the processors. The processors may form part of a computer system CL forming part of a holistic lithographic system. Alternatively or additionally, the methods may be performed on a computer system separate from the lithographic system.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A method comprising:
obtaining a trained model configured to infer a preferred sampling scheme for a substrate based on measurement data comprising sampling locations on the substrate and corresponding measurement values; and
using, by a hardware computer system, current measurement data associated with a current substrate as input for the trained model to determine whether further measurement on the current substrate is required.

2. The method of claim 1, wherein the model is based on a neural network.

3. The method of claim 1, further comprising inputting pre-exposure data and/or context data associated with the current substrate to the trained model.

4. The method of claim 3, wherein the pre-exposure data comprises previous measurement data associated with sampling locations and corresponding measurement values of one or more previous substrates.

5. The method of claim 1, further comprising configuring the trained model based on the current measurement data.

6. A method for inferring a current sampling scheme for one or more current substrates, the method comprising:
obtaining a first model trained to infer an optimal sampling scheme based on inputting context and/or pre-exposure data associated with one or more previous substrates, wherein the first model is trained in dependency of an outcome of a second model configured to discriminate between the inferred optimal sampling scheme and a pre-determined optimal sampling scheme; and
using, by a hardware computer system, the obtained first model to infer the current sampling scheme based on inputting context and/or pre-exposure data associated with the one or more current substrates.

7. The method of claim 6, wherein the first model is a generative model and the second model is a discriminative model and the first and second models constitute a Generative Adversarial Network (GAN).

8. The method of claim 6, wherein the first model is trained using input data comprising the context and/or pre-exposure data and measurement data associated with a dense sampling scheme being more dense than the inferred current sampling scheme.

9. The method of claim 8, wherein the dense sampling scheme is configured to be a sampling scheme expected to suffice for any condition of the substrate, wherein the condition is characterized by context and/or pre-exposure data associated with the substrate.

10. A method for providing a decision on stopping or continuing performing measurements on sampling locations on one more substrates, the method comprising:
obtaining an initial set of measurement values corresponding to an initial sampling scheme;
obtaining a model comprising:
i) a first model trained to infer from a set of measurement values whether one or more requirements imposed by a process monitoring and/or process control strategy are met; and ii) a second model trained to infer from a set of measurement values that one or more further measurement values need to be acquired before meeting the requirements imposed by the process monitoring and/or process control strategy; and
inputting the initial set of measurement values to the model to obtain the decision, wherein the decision is based on balancing the output of the first and the second model.

11. The method of claim 10, wherein the first model is a generative model and the second model is a discriminative model and the model is a Generative Adversarial Network (GAN).

12. A computer program product comprising a non-transitory computer-readable medium comprising computer readable instructions therein, the instructions, when executed by one or more processors are configured to cause the one or more processors to at least perform the method of claim 1.

13. A computer program product comprising a non-transitory computer-readable medium comprising computer readable instructions therein, the instructions, when executed by one or more processors are configured to cause the one or more processors to at least perform the method of claim 6.

14. The computer program product of claim 13, wherein the first model is a generative model and the second model is a discriminative model and the first and second models constitute a Generative Adversarial Network (GAN).

15. A computer program product comprising a non-transitory computer-readable medium comprising computer readable instructions therein, the instructions, when executed by one or more processors are configured to cause the one or more processors to at least perform the method of claim 10.

16. The computer program product of claim 15, wherein the first model is a generative model and the second model is a discriminative model and the model is a Generative Adversarial Network (GAN).

17. The computer program product of claim 12, wherein the model is based on a neural network.

18. The computer program product of claim 12, wherein the instructions are further configured to cause the one or more processors to input pre-exposure data and/or context data associated with the current substrate to the trained model.

19. The computer program product of claim 18, wherein the pre-exposure data comprises previous measurement data associated with sampling locations and corresponding measurement values of one or more previous substrates.

20. The computer program product of claim 12, wherein the instructions are further configured to cause the one or more processors to configure the trained model based on the current measurement data.
